(19) United States
(12) Patent Application Publication
(10) Pub. No.: US 2022/0266419 A1
(43) Pub. Date: Aug. 25, 2022

(54) GRINDING METHOD AND GRINDING APPARATUS

(71) Applicant: OKAMOTO MACHINE TOOL WORKS, LTD., Gunma (JP)

(72) Inventors: Tsubasa BANDO, Gunma (JP); Eiichi YAMAMOTO, Gunma (JP); Takahiko MITSUI, Gunma (JP); Yu HONDA, Gunma (JP)

(21) Appl. No.: 17/669,829

(22) Filed: Feb. 11, 2022

(30) Foreign Application Priority Data
Feb. 19, 2021 (JP) 2021-025126

(51) Int. Cl. B24B 49/12; B24B 7/04; B24B 7/22; B24B 49/04

(52) U.S. Cl. CPC B24B 49/12; B24B 7/04; B24B 7/228; B24B 49/04

(57) ABSTRACT

There is provided a grinding method for grinding a substrate with a grinding wheel. A dissimilar material portion made of a material different from a main constituent material of the substrate is embedded in the substrate. The grinding method includes: lowering the grinding wheel toward the substrate rotating while rotating the grinding wheel, and grinding the substrate by the grinding wheel; continuously imaging a processed surface of the substrate by an image sensor during grinding the substrate; analyzing an amount of exposure of the dissimilar material portion based on data of an image captured by the image sensor; and continuously grinding the substrate from a state where the dissimilar material portion begins to be exposed to a stage where the amount of exposure of the dissimilar material portion reaches a predetermined set value, based on the amount of exposure analyzed.

### CROSS-REFERENCE TO RELATED APPLICATION

This application claims priority from Japanese Patent Application No. 2021-025126 filed with the Japan Patent Office on Feb. 19, 2021, the entire content of which is hereby incorporated by reference.

### BACKGROUND

### 1. Technical Field

The present disclosure relates to a grinding method and a grinding apparatus.

### 2. Related Art

Conventionally, in manufacturing semiconductor substrates and the like, there has been known a technique of grinding and thinning a substrate in which an electrode or the like made of a material different from a main constituent material is embedded inside a layer forming the substrate.

For example, JP-A-2019-140162 discloses a method for manufacturing a semiconductor device using an insulating isolation Si substrate with a through silicon via (TSV) embedded, in which a Si support substrate is removed by a grinding method or the like to expose a Cu film of the through silicon via.

Further, for example, JP-A-2020-102481 discloses a technique for grinding a large composite substrate including resin, metal, and a semiconductor device chip by fan out panel level package (FOPLP) technique.

### SUMMARY

A grinding method according to an embodiment of the present disclosure is configured as follows. The grinding method is for grinding a substrate with a grinding wheel, and a dissimilar material portion made of a material different from a main constituent material of the substrate is embedded in the substrate. The grinding method includes: lowering the grinding wheel toward the substrate rotating while rotating the grinding wheel, and grinding the substrate by the grinding wheel; continuously imaging a processed surface of the substrate by an image sensor during grinding the substrate; analyzing an amount of exposure of the dissimilar material portion based on data of an image captured by the image sensor; and continuously grinding the substrate from a state where the dissimilar material portion begins to be exposed to a stage where the amount of exposure of the dissimilar material portion reaches a predetermined set value, based on the amount of exposure analyzed.

### BRIEF DESCRIPTION OF THE DRAWINGS

FIG. 1 is a diagram illustrating a schematic configuration of a grinding apparatus according to an embodiment of the present disclosure;

FIG. 2 is a diagram illustrating the vicinity of a tip of an image sensor of the grinding apparatus according to the embodiment of the present disclosure;

FIG. 3A is a diagram illustrating a schematic form of a work before grinding processing in a grinding method according to the embodiment of the present disclosure;

FIG. 3B is a diagram illustrating the schematic form of the work during grinding processing;

FIG. 3C is a diagram illustrating the schematic form of the work after grinding processing; and

FIG. 4 is a diagram illustrating a schematic configuration of a grinding apparatus according to another embodiment of the present disclosure.

### DETAILED DESCRIPTION

In the following detailed description, for purpose of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

However, the above conventional substrate grinding method and apparatus have a point to be improved in order to reduce processing time and improve production efficiency of a substrate.

Specifically, in a process of grinding the substrate in which dissimilar material portions made of a material different from a main constituent material of a layer forming the substrate are embedded, it may be required to expose all the dissimilar material portions. For example, in the process of grinding the substrate in which a Cu via or the like is embedded inside a mold resin, a silicon wafer, or the like, it is required to expose an entire surface of the Cu via or the like.

In the above-mentioned conventional grinding method, grinding processing is started, and the grinding processing is performed to an end point thickness set in advance, and then the grinding processing is stopped and a rotation of a work is stopped. Thereafter, exposure of the Cu via on a processed surface is observed by visual inspection or microscopic inspection.

Further, in a method for measuring a dimension of the processed surface with a contact-type thickness measuring device, it is necessary to end the grinding processing and stop the rotation of the work in order to measure a thickness of the substrate.

When it is determined that the Cu via is not exposed on the entire surface as a result of visual inspection or microscopic inspection, or when it is determined that the thickness of the substrate does not reach a predetermined dimension as a result of measurement by the thickness measuring device, the grinding processing is performed again.

In a situation where high precision processing is required for an extremely thin substrate, it is difficult to expose the entire surface of the Cu via in a single grinding processing and finish it to a predetermined size. Therefore, the above-mentioned grinding processing, measurement, and visual inspection or microscopic inspection are repeatedly performed until the entire surface of the Cu via is exposed and reaches a predetermined target dimension.

Therefore, in the above conventional grinding, it is necessary to repeatedly perform and stop the grinding processing, and the number of times of grinding processing, the number of measurements and the number of inspections are large, and thus it is difficult to reduce the processing time. This has been a problem in improving productivity of the substrate.

In particular, when grinding a substrate having a structure in which the dissimilar material portions such as Cu (copper) are embedded in a resin substrate, if a large amount of filler such as spherical silica is contained in the resin of the resin substrate, that is, for example if the filler is contained in an amount of 50% or more, it is difficult to measure the thickness of the resin by non-contact near-infrared light. This is because infrared light is scattered by the filler, so that it is not possible to obtain an interference waveform due to infrared light from a front surface of the substrate and a back surface of the substrate.

The present disclosure has been made in view of the above circumstances, and an object of the present disclosure is to provide a grinding method and a grinding apparatus capable of grinding the substrate in which the dissimilar material portions are embedded, with high precision in a short time.

A grinding method according to the present disclosure is for grinding a substrate with a grinding wheel, and a dissimilar material portion made of a material different from a main constituent material of the substrate is embedded in the substrate. The grinding method includes: lowering the grinding wheel toward the substrate rotating while rotating the grinding wheel, and grinding the substrate by the grinding wheel; continuously imaging a processed surface of the substrate by an image sensor during grinding the substrate; analyzing an amount of exposure of the dissimilar material portion based on data of an image captured by the image sensor; and continuously grinding the substrate from a state where the dissimilar material portion begins to be exposed to a stage where the amount of exposure of the dissimilar material portion reaches a predetermined set value, based on the amount of exposure analyzed.

Moreover, a grinding apparatus according to the present disclosure includes: a substrate chuck that holds and rotates a substrate in which a dissimilar material portion made of a material different from a main constituent material is embedded; a grinding head that holds a grinding wheel facing the substrate held by the substrate chuck and rotates about a rotation axis at a position offset in a radial direction from a rotation axis of the substrate chuck; a feed mechanism that feeds the grinding head or the substrate chuck in a direction in which the grinding wheel and the substrate approach or separate from each other; an image sensor that images a processed surface of the substrate in a process of grinding the rotating substrate with the rotating grinding wheel; and an image analysis apparatus that analyzes an amount of exposure of the dissimilar material portion based on data of an image of the processed surface captured by the image sensor. The feed mechanism is controlled based on the amount of exposure analyzed by the image analysis apparatus, and the dissimilar material portion exposed from the processed surface is ground.

The grinding method according to the present disclosure is for grinding the substrate with the grinding wheel, and the dissimilar material portion made of the material different from the main constituent material of the substrate is embedded in the substrate. The grinding method includes: lowering the grinding wheel toward the substrate rotating while rotating the grinding wheel, and grinding the substrate by the grinding wheel; continuously imaging the processed surface of the substrate by the image sensor during grinding the substrate; analyzing the amount of exposure of the dissimilar material portion based on the data of the image captured by the image sensor; and continuously grinding the substrate from the state where the dissimilar material portion begins to be exposed to the stage where the amount of exposure of the dissimilar material portion reaches the predetermined set value, based on the amount of exposure analyzed. Thus, it is possible to accurately grasp a grinding state without temporarily stopping the grinding processing in order to detect the exposure of the dissimilar material portion like the conventional technique. Therefore, it is possible to efficiently grind the substrate in which the dissimilar material portion is embedded with high precision in a short time without repeatedly performing and stopping the grinding processing.

Further, according to the grinding method of the present disclosure, the substrate may be a resin substrate, and the dissimilar material portion may contain a metal material. The grinding method of the present disclosure can expose the dissimilar material portion made of the metal material with high efficiency and high precision by grinding the resin substrate in which the metal material is embedded as described above.

Further, according to the grinding method of the present disclosure, image capturing by the image sensor may be performed using a spot strobe generation light source with an image capturing time of 1 to 100 microseconds. With such a configuration, it is possible to detect the dissimilar material portion exposed during the grinding processing with high precision and at a high speed. Therefore, it is possible to efficiently grind the substrate in a short time without repeatedly performing and stopping the grinding processing.

Further, the grinding apparatus according to the present disclosure includes: the substrate chuck that holds and rotates the substrate in which the dissimilar material portion made of the material different from the main constituent material is embedded; the grinding head that holds the grinding wheel facing the substrate held by the substrate chuck and rotates about the rotation axis at the position offset in the radial direction from the rotation axis of the substrate chuck; the feed mechanism that feeds the grinding head or the substrate chuck in the direction in which the grinding wheel and the substrate approach or separate from each other; the image sensor that images the processed surface of the substrate in the process of grinding the rotating substrate with the rotating grinding wheel; and the image analysis apparatus that analyzes the amount of exposure of the dissimilar material portion based on the data of the image of the processed surface captured by the image sensor. The feed mechanism is controlled based on the amount of exposure analyzed by the image analysis apparatus, and the dissimilar material portion exposed from the processed surface is ground. Thus, it is possible to efficiently grind the substrate with high precision in a short time, and to improve the productivity of the substrate.

Hereinafter, a grinding apparatus 1 according to an embodiment of the present disclosure and a grinding method using the grinding apparatus 1 will be described in detail with reference to the drawings.

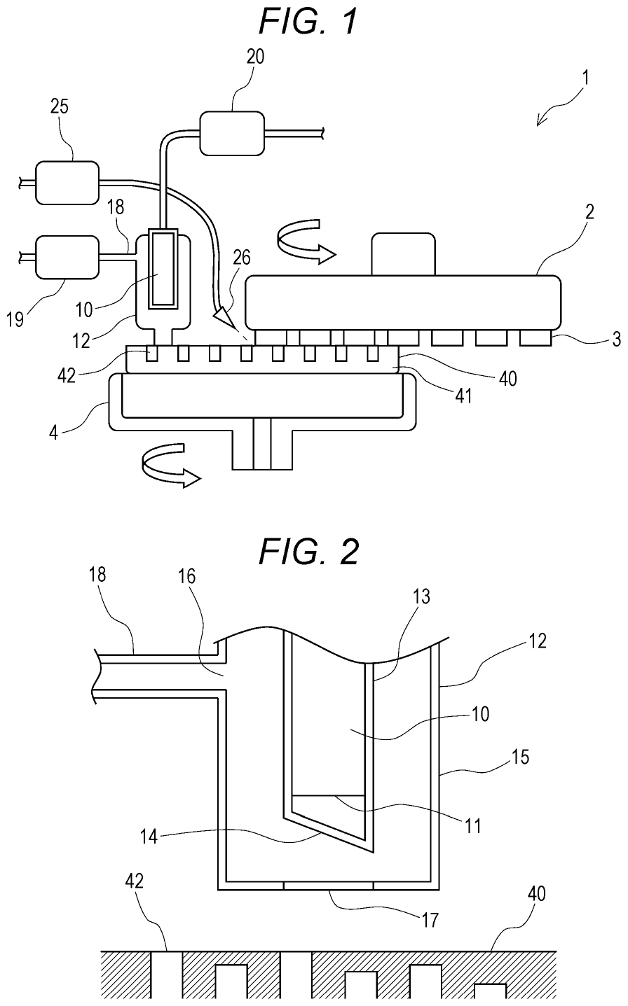

FIG. 1 is a diagram illustrating a schematic configuration of the grinding apparatus 1 according to the embodiment of the present disclosure.

As illustrated in FIG. 1, the grinding apparatus 1 is a processing apparatus used for processing to grind a main surface of a substrate 40. Specifically, the grinding apparatus 1 is used in the process of grinding a flat surface of the substrate 40, in which a dissimilar material portion 42 made of a dissimilar material is embedded, to expose the dissimilar material portion 42 embedded in the substrate 40.

In the substrate 40 to be processed by the grinding apparatus 1, the dissimilar material portion 42 made of a material different from a main material forming a main body portion 41 of the substrate 40 is embedded. For example, in the substrate 40, the dissimilar material portion 42 such as a Cu (copper) electrode different from the main material forming the main body portion 41 is embedded in the main body portion 41 made of a resin material or the like as a main constituent material.

The grinding apparatus 1 includes a substrate chuck 4 for holding the substrate 40, a grinding head 2 for holding a grinding wheel 3, a feed mechanism (not illustrated) for feeding the grinding head 2, an image sensor 10 for imaging the processed surface of the substrate 40, and an image analysis apparatus 20 for analyzing the amount of exposure of the dissimilar material portion 42 from image data of the image sensor 10.

The substrate chuck 4 is a porous chuck that adsorbs and holds the substrate 40. The substrate chuck 4 has a substantially flat plate shape and is mounted above a grinding table (not illustrated). The substrate chuck 4 is, for example, a vacuum chuck, and the substrate chuck 4 is provided with a vacuum pump (not illustrated) for adsorbing the substrate 40 by creating a negative pressure inside the substrate chuck 4.

The grinding table on which the substrate chuck 4 is placed is rotationally driven by a driving unit (not illustrated). Thus, the substrate chuck 4 rotates horizontally. At the time of grinding processing, the substrate 40 is placed on an upper surface of the substrate chuck 4, and the substrate 40 rotates horizontally together with the substrate chuck 4.

The grinding head 2 is a mechanism for holding and rotating the grinding wheel 3. The grinding head 2 is provided so that its rotation axis is offset in the radial direction from the rotation axis of the substrate chuck 4. The grinding wheel 3 is held below the grinding head 2 so as to face an upper surface of the substrate 40 held by the substrate chuck 4.

The grinding wheel 3 is a cup wheel type grinding wheel that grinds the horizontally rotating substrate 40 from above. The grinding wheel 3 has a substantially disk-shaped cup wheel that is held by the grinding head 2 and rotates horizontally. A cutting edge of the grinding wheel 3 is attached in a substantially circular shape near a lower peripheral edge of the cup wheel.

Although not illustrated, the feed mechanism is, for example, a mechanism having a ball screw or the like and feeding the grinding head 2 in a rotation axis direction, that is, in an up-down direction so that the grinding wheel 3 and the substrate 40 approach or separate from each other. Note that the feed mechanism may be provided on the substrate chuck 4 side so as to feed the substrate 40 in the up-down direction.

The grinding head 2 is driven by a driving unit (not illustrated) to rotate horizontally, and is fed in the up-down direction by the feed mechanism (not illustrated). That is, the grinding wheel 3 is fed by the feed mechanism while rotating horizontally together with the grinding head 2, and moves in a direction approaching or separating from the substrate 40. In the process of grinding the substrate 40, the cutting edge at a lower portion of the horizontally rotating grinding wheel 3 comes into contact with the upper surface of the substrate 40 which is adsorbed to the upper surface of the substrate chuck 4 and rotates horizontally, and the substrate 40 is ground.

Further, the grinding apparatus 1 has a grinding water supply apparatus 25 and a grinding water supply nozzle 26 provided in the grinding water supply apparatus 25. The grinding water supply apparatus 25 is an apparatus that supplies pure water to the vicinity of a contact portion between the substrate 40 and the grinding wheel 3 through the grinding water supply nozzle 26. That is, pure water supplied from the grinding water supply apparatus 25 is sprayed from a spray port of the grinding water supply nozzle 26 toward the vicinity of the contact portion between the upper surface of the substrate 40 and the cutting edge of the grinding wheel 3.

The image sensor 10 is a device that images the processed surface of the substrate 40. The image sensor 10 is an imaging sensor using an imaging element such as a charge-coupled device (CCD) or a complementary metal-oxide semiconductor (CMOS).

In particular, the image sensor 10 is preferably a sensor using a CMOS imaging element in order to image the processed surface of the rotating substrate 40 at a high speed and obtain high precision image data that enables the grinding processing for exposing the dissimilar material portion 42.

Further, although not illustrated, the image sensor 10 has a light source for irradiating light in the vicinity of an imaging portion of the substrate 40, and receives a reflected light from the substrate 40 to capture the image. Since the light source for emitting such strong light is provided, it is possible to capture the image at a high speed and with high precision for achieving the grinding processing.

The image sensor 10 is provided at a position above the substrate 40 held by the substrate chuck 4 and not in contact with the grinding wheel 3 in the process of grinding the horizontally rotating substrate 40 with the horizontally rotating grinding wheel 3. In other words, the image sensor 10 is provided at a position away from the grinding wheel 3 in a grinding process, and images the processed surface of the substrate 40 away from the grinding wheel 3.

The image analysis apparatus 20 is an apparatus that analyzes the amount of exposure of the dissimilar material portion 42 from the image data of the processed surface of the substrate 40 captured by the image sensor 10. The image analysis apparatus 20 is connected to the image sensor 10 and is connected to a control apparatus (not illustrated) that controls the grinding processing of the grinding apparatus 1.

The image data analyzed by the image analysis apparatus 20 is sent to the control apparatus. The control apparatus controls the driving unit for rotating the substrate 40, the driving unit for rotating the grinding wheel 3, and the feed mechanism that moves the substrate 40 and the grinding wheel 3 relative to each other, on the basis of the amount of exposure of the dissimilar material portion 42 analyzed by the image analysis apparatus 20. Thus, the dissimilar material portion 42 exposed from the processed surface of the substrate 40 is ground.

That is, the grinding apparatus 1 continuously images the processed surface of the substrate 40 with the image sensor 10 during the grinding processing, and continuously grinding the substrate 40 from the state (stage) where the dissimilar material portion 42 begins to be exposed to the stage where the amount of exposure of the dissimilar material portion 42 reaches the predetermined set value.

The grinding apparatus 1 can efficiently perform high precision continuous grinding of the substrate 40 in a short time without repeatedly performing and stopping the grinding processing as in the related art. Therefore, the grinding apparatus 1 can improve the productivity of the substrate 40.

The grinding apparatus 1 has an imaging water supply apparatus 19 that supplies pure water, in the vicinity of the imaging portion by the image sensor 10. Specifically, the vicinity of a tip of the image sensor 10 is covered with a housing 12, and a pipe 18 for supplying pure water from the imaging water supply apparatus 19 is connected to the housing 12. With such a configuration, pure water is supplied from the imaging water supply apparatus 19 to an inside of the housing 12 through the pipe 18. Note that the imaging water supply apparatus 19 may also serve as the above-mentioned grinding water supply apparatus 25.

FIG. 2 is a diagram illustrating the vicinity of the tip of the image sensor 10 of the grinding apparatus 1.

As illustrated in FIG. 2, the vicinity of the tip of the image sensor 10, that is, the vicinity of an imaging port 11 is covered with the housing 12. At the time of grinding processing, pure water is supplied from the imaging water supply apparatus 19 (see FIG. 1) to the vicinity of the imaging port 11.

Specifically, the housing 12 has an inner housing 13 that covers the vicinity of the imaging port 11 of the image sensor 10, and an outer housing 15 that covers the inner housing 13. Then, a region sandwiched between the inner housing 13 and the outer housing 15, that is, the region outside the inner housing 13 and inside the outer housing 15 is a flow path for pure water.

An imaging window portion 14 is formed in the inner housing 13 near the imaging port 11. The imaging window portion 14 transmits the light emitted from the light source (not illustrated) and also transmits the reflected light from the imaging portion of the substrate 40. The imaging window portion 14 transmits the light for image capturing, but is not an opening through which liquid can flow. Pure water supplied from the imaging water supply apparatus 19 does not flow from the inside of the housing 12 to the image sensor 10 side.

Therefore, grinding debris or the like of the substrate 40 does not adhere to the imaging port 11 of the image sensor 10, and deterioration of image capturing performance is suppressed. Further, there is no possibility that the element of the image sensor 10, wiring system, or the like gets wet with pure water to be damaged.

A water outlet 17 that allows the pure water in the housing 12 to flow out toward the substrate 40 is formed in a lower portion of the outer housing 15. That is, in the grinding processing, the pure water supplied from the imaging water supply apparatus 19 into the housing 12 passes through the vicinity of the imaging port 11 of the image sensor 10, that is, the vicinity of the imaging window portion 14 of the inner housing 13, and flows out in the vicinity of the imaging portion of the substrate 40.

With the above configuration, it is possible to prevent the grinding debris or the like of the substrate 40 from being scattered or flowing in the vicinity of the imaging port 11 of the image sensor 10. For example, even when grinding the resin substrate 40 in which the dissimilar material portion 42 made of the metal material is embedded, it is possible to prevent the imaging port 11 of the image sensor 10 and the imaging window portion 14 of the housing 12 from being damaged by hard metal debris. Therefore, it is possible to suppress reduction in imaging precision due to the grinding debris or the like, thereby capturing the image with high precision.

Further, as described above, the image sensor 10 has the light source that irradiates the substrate 40 with light and a camera that images the reflected light. The light source of the image sensor 10 is, for example, a spot strobe generation type. Then the image capturing time of the camera of the image sensor 10, that is, a shutter speed is, for example, 1 to 100 microseconds. Note that the image capturing time of the image sensor 10 is set in synchronization with a rotation speed of the substrate 40. With such a configuration, the dissimilar material portion 42 exposed during the grinding processing can be detected with high precision and at a high speed.

In this way, the grinding apparatus 1 can continuously capture at a high speed by the image sensor 10 the image of the processed surface of the substrate 40 that rotates horizontally during grinding. For example, even if the substrate 40 is a FOPLP substrate of about 300 mm square and its rotation speed is about 300 rpm, it is possible to image the processed surface of the substrate 40 with high precision.

Then, the image analysis apparatus 20 analyzes color and an image pattern of the image data with high precision, and accurately grasps an exposure state of the dissimilar material portion 42. Then, when the amount of exposure of the dissimilar material portion 42 reaches a preset target value, the grinding apparatus 1 stops the grinding processing.

As described above, the grinding apparatus 1 can collect high precision image data without image deletion by the image sensor 10 that captures the image data at a high speed. Therefore, it is possible to continuously and reliably grind the substrate 40 without stopping to an end point of a processing target position, without repeatedly start and stop grinding in order to measure the thickness of the substrate 40 with a contact type sensor, like the grinding apparatus in the related art.

Further, the imaging window portion 14 of the housing 12 is provided to be inclined with respect to the processed surface of the substrate 40, that is, a horizontal plane. Specifically, a tilt angle of the imaging window portion 14 with respect to the processed surface of the substrate 40 is, for example, 5 to 15 degrees, preferably 5 to 12 degrees, and more preferably 5 to 10 degrees.

Since the tilt angle of the imaging window portion 14 is 5 degrees or more in this way, it is possible to suppress diffuse reflection in the imaging window portion 14, thereby improving accuracy of the image data. Therefore, it is possible to obtain the high precision image data and perform high precision grinding processing.

On the other hand, when the tilt angle of the imaging window portion 14 is larger than 15 degrees, since angle deviation of light beam is large due to refraction, a distance from an imaging target portion is large, and an error occurs in a measured value. Therefore, the tilt angle within the above-mentioned range is suitable. The high precision grinding processing is achieved by obtaining high precision imaging data with a suitable tilt angle.

Although not illustrated, the grinding apparatus 1 includes a focus mechanism for adjusting a position of the image sensor 10 and a tilt mechanism for adjusting a tilt of the image sensor 10. The focus mechanism can finely adjust a position of at least one of the light source of the image sensor 10, the camera, and the imaging window portion 14, specifically a height from the substrate 40. The tilt mechanism can finely adjust a tilt of at least one of the light source of the image sensor 10, the camera, and the imaging window portion 14, that is, a tilt angle with respect to the processed surface of the substrate 40. With such a configuration, the image sensor 10 can obtain the high precision imaging data.

Next, the grinding method using the grinding apparatus 1 will be described in detail with reference to FIGS. 1, 2, and 3A to 3C.

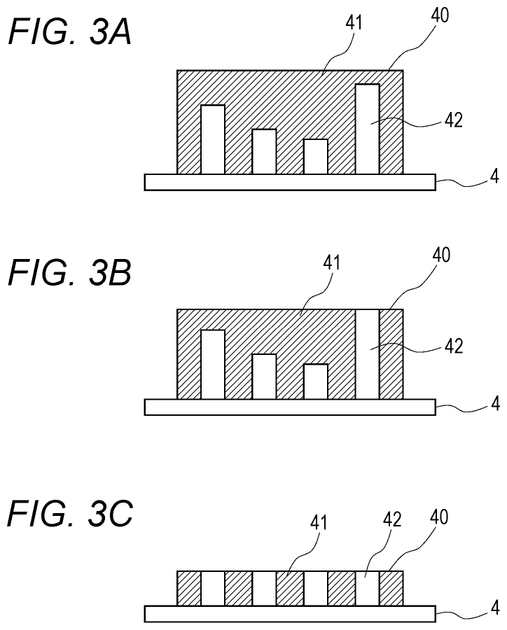

FIGS. 3A to 3C are diagrams illustrating the vicinity of a work in the grinding method according to the embodiment of the present disclosure. FIG. 3A schematically illustrates a form of the substrate 40 before grinding processing, FIG. 3B schematically illustrates that during grinding processing, and FIG. 3C schematically illustrates that after grinding processing.

As illustrated in FIG. 3A, the dissimilar material portion 42 made of the material different from the main material forming the main body portion 41 is embedded inside the main body portion 41 of the substrate 40 to be processed. That is, at least the main body portion 41 and the dissimilar material portion 42 embedded in the main body portion 41 are made of different materials.

Specifically, the substrate 40 to be processed by the grinding apparatus 1 is the resin substrate, a semiconductor substrate, an insulating substrate, or the like, and main constituent materials of the substrate 40 are various type resins, silicon, silicon carbide (SiC), gallium arsenide, sapphire, or the like.

The grinding apparatus 1 exhibits excellent processing performance particularly for the resin substrate. For example, the grinding apparatus 1 is used for grinding a large composite substrate including mold resin, metal, and a semiconductor device chip by FOPLP technology.

Further, the grinding apparatus 1 can also be used in other substrate manufacturing processes using the mold resin, for example, fan out wafer level package (FOWLP) or system in a package (SiP).

As the main material constituting the substrate 40, various resin materials such as epoxy-based resin, urethane resin, silicone resin, and polyimide resin can be employed. Further, the resin material constituting the substrate 40 as the resin substrate may contain a silica filler for improving electrical characteristics.

The dissimilar material portion 42 embedded in the substrate 40 may be an electrode or the like containing the metal material such as Cu, gold (Au), titanium (Ti), aluminum (Al), or platinum (Pt). Further, the dissimilar material portion 42 may include a semiconductor material, an insulating material, or the like.

As illustrated in FIGS. 1 and 3A, in the grinding process of the substrate 40, the substrate 40 is held on the upper surface of the substrate chuck 4 and driven by the driving unit to rotate horizontally. The grinding wheel 3 driven by the driving unit (not illustrated) to rotate horizontally is lowered toward the processed surface of the rotating substrate 40, that is, the upper surface of the substrate 40. The processed surface of the substrate 40 is ground by the cutting edge of the lowered grinding wheel 3 contacting the processed surface of the substrate 40. The processed surface of the substrate 40 is ground in this way by a down-feed grinding method in which both the substrate 40 and the grinding wheel 3 are rotated and the grinding wheel 3 is lowered to grind the substrate 40.

During the grinding processing, the processed surface of the substrate 40 is continuously imaged by the image sensor 10. Then, the image data obtained by the image sensor 10 is analyzed by the image analysis apparatus 20. That is, the amount of exposure of the dissimilar material portion 42 can be obtained from color information and image pattern information of the processed surface.

When the grinding processing is performed, the main body portion 41 of the upper portion of the substrate 40 is ground, and as illustrated in FIG. 3B, the dissimilar material portion 42 begins to be exposed. As described above, the processed surface of the substrate 40 is imaged by the image sensor 10, and the image data is analyzed by the image analysis apparatus 20, so that the exposure state of the dissimilar material portion 42 is accurately detected.

Specifically, when the image analysis apparatus 20 detects a color pattern specified in advance in the image data of the processed surface of the substrate 40, the amount of exposure of the dissimilar material portion 42 is analyzed on the basis of the number of cells of the color pattern. Thus, the degree of exposure of the dissimilar material portion 42 can be accurately obtained.

Therefore, the grinding method of the present embodiment does not require a step of temporally stopping the grinding processing by the grinding wheel 3 to stop the rotation of the substrate 40 and measuring the thickness of the substrate 40 of the dissimilar material portion 42 using the contact type sensor or the like, like the grinding method in the related art.

Subsequently, as illustrated in FIG. 3C, when upper ends of all the dissimilar material portions 42 are exposed from the substrate 40, the image analysis apparatus 20 analyzes the image data, to accurately detect that the amount of exposure of the dissimilar material portion 42 has reached a set end value.

Specifically, the image analysis apparatus 20 determines that the amount of exposure of the dissimilar material portion 42 has reached the end value when the number of cells of the color pattern specified in advance reaches a certain condition or more.

Then, the control device controls the grinding wheel 3 to be separated from the processed surface of the substrate 40. Subsequently, the grinding wheel 3 and the substrate 40 are controlled to stop the rotation, to end the grinding processing.

As described above, according to the grinding method according to the present embodiment, the grinding processing is continued from the state where the dissimilar material portion 42 begins to be exposed to the stage where the amount of exposure of the dissimilar material portion 42 reaches the predetermined set value. That is, even if the substrate 40 is the resin substrate in which the dissimilar material portion 42 such as metal is embedded, continuous and efficient grinding processing with excellent productivity can be performed without repeatedly performing and stopping the grinding processing.

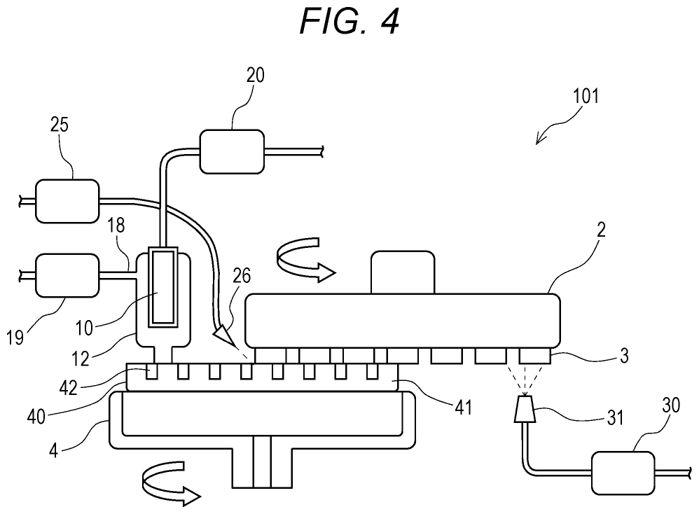

Next, a grinding apparatus 101 according to another embodiment of the present disclosure will be described in detail with reference to FIG. 4.

FIG. 4 is a diagram illustrating the schematic configuration of the grinding apparatus 101. Components obtaining the same or similar operations or effects as those of the above-described embodiment are denoted by the same reference numerals, and description thereof will be omitted.

As illustrated in FIG. 4, the grinding apparatus 101 includes a high pressure water generator 30 that supplies high pressure water, and a high pressure water nozzle 31 that sprays the high pressure water supplied from the high pressure water generator 30 to the grinding wheel 3.

The high pressure water nozzle 31 is provided below and in the vicinity of the grinding wheel 3 that is not in contact with the processed surface of the substrate 40 during the grinding processing. The high pressure water nozzle 31 sprays the high pressure water toward the cutting edge of the grinding wheel 3 that is not in contact with the processed surface of the substrate 40.

A pressure of the high pressure water sprayed from the high pressure water nozzle 31 is, for example, 3 MPa to 20 MPa, and preferably 10 MPa to 14 MPa. A spray angle of the high pressure water sprayed from the high pressure water nozzle 31 is preferably 5 to 20 degrees, and more preferably 8 to 12 degrees.

Further, a plurality of high pressure water nozzles 31 may be provided. Furthermore, the high pressure water nozzle 31 may have a mechanism for swinging at a speed of 1 to 20 mm/sec and with a swing width of 1 to 10 mm.

Such a configuration in which the high pressure water generator 30 and the high pressure water nozzle 31 are provided is particularly effective when the dissimilar material portion 42 made of the metal material is embedded in the resin substrate 40. That is, the high pressure water sprayed from the high pressure water nozzle 31 can blow off the metal debris and the like adhering to the grinding wheel 3 and suppress clogging of the grinding wheel 3.

Since the clogging of the grinding wheel 3 can be suppressed in this way, it is possible to perform continuous grinding processing for a long time. Therefore, by a combination of a configuration that suppresses the clogging of the grinding wheel 3 and a configuration that accurately detects an exposed state of the dissimilar material portion 42 by using the image sensor 10 capable of high speed imaging and performs continuous grinding processing, it is possible to achieve continuous grinding processing with high efficiency and high precision, which cannot be achieved in the related art.

Further, the grinding method according to the above embodiments is a processing method completely different from the conventional cutting processing with a milling cutter using a diamond bite. According to the grinding method of the above embodiments, excellent processing performance that cannot be achieved by the cutting processing with the milling cutter can be obtained, and it is possible to perform efficient and high flatness grinding processing at low cost.

Note that the present disclosure is not limited to the above embodiments, and various modifications can be made without departing from the gist of the present disclosure.

The foregoing detailed description has been presented for the purposes of illustration and description. Many modifications and variations are possible in light of the above teaching. It is not intended to be exhaustive or to limit the subject matter described herein to the precise form disclosed. Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims appended hereto.

What is claimed is:

1. A grinding method for grinding a substrate with a grinding wheel, wherein
a dissimilar material portion made of a material different from a main constituent material of the substrate is embedded in the substrate, and
the grinding method comprises:
lowering the grinding wheel toward the substrate rotating while rotating the grinding wheel, and grinding the substrate by the grinding wheel;
continuously imaging a processed surface of the substrate by an image sensor during grinding the substrate;
analyzing an amount of exposure of the dissimilar material portion based on data of an image captured by the image sensor; and
continuously grinding the substrate from a state where the dissimilar material portion begins to be exposed to a stage where the amount of exposure of the dissimilar material portion reaches a predetermined set value, based on the amount of exposure analyzed.

2. The grinding method according to claim 1, wherein the substrate is a resin substrate, and the dissimilar material portion contains a metal material.

3. The grinding method according to claim 1, wherein image capturing by the image sensor is performed using a spot strobe generation light source with an image capturing time of 1 to 100 microseconds.

4. A grinding apparatus comprising:
a substrate chuck that holds and rotates a substrate in which a dissimilar material portion made of a material different from a main constituent material is embedded;
a grinding head that holds a grinding wheel facing the substrate held by the substrate chuck and rotates about a rotation axis at a position offset in a radial direction from a rotation axis of the substrate chuck;
a feed mechanism that feeds the grinding head or the substrate chuck in a direction in which the grinding wheel and the substrate approach or separate from each other;
an image sensor that images a processed surface of the substrate in a process of grinding the rotating substrate with the rotating grinding wheel; and
an image analysis apparatus that analyzes an amount of exposure of the dissimilar material portion based on data of an image of the processed surface captured by the image sensor, wherein
the feed mechanism is controlled based on the amount of exposure analyzed by the image analysis apparatus, and the dissimilar material portion exposed from the processed surface is ground.
